(19) United States
(12) Patent Application Publication
(10) Pub. No.: US 2025/0141208 A1
(43) Pub. Date: May 1, 2025

(54) COMMUNICATION DEVICE

(71) Applicant: Panasonic Automotive Systems Co., Ltd., Kanagawa (JP)

(72) Inventors: Shunsuke KATSUMURA, Tokyo (JP); Tatsuya INOUE, Osaka (JP); Hideaki TOKUNAGA, Osaka (JP); Keiji KOBAYASHI, Osaka (JP); Kenji NOZOE, Fukui (JP)

(21) Appl. No.: 19/009,296

(22) Filed: Jan. 3, 2025

Related U.S. Application Data
(63) Continuation of application No. PCT/JP2024/001853, filed on Jan. 23, 2024.

(30) Foreign Application Priority Data
Mar. 22, 2023 (JP) 2023-045602

(51) Int. Cl. H02H 3/20; H03H 1/00

(52) U.S. Cl. CPC H02H 3/20; H03H 1/00

(57) ABSTRACT

A communication device according to the present disclosure transmits a high-frequency signal. the communication device includes at least one signal line, at least one overvoltage protection component, and at least one impedance component. The at least one signal line transmits the high-frequency signal and includes a first signal line. The at least one overvoltage protection component is connected to the first signal line and includes a first overvoltage protection component. The at least one impedance component is connected in series with the first overvoltage protection component between the first signal line and a ground. The at least one impedance component achieves both reduction of current wraparound via the ground due to a high-frequency component of an electrostatic noise applied to the communication device and reduction of a current flowing through the first overvoltage protection component due to a low-frequency component of the electrostatic noise.

### CROSS-REFERENCE TO RELATED APPLICATIONS

This application is a continuation of International Application No. PCT/JP2024/001853, filed on Jan. 23, 2024 which claims the benefit of priority of the prior Japanese Patent Application No. 2023-045602, filed on Mar. 22, 2023, the entire contents of which are incorporated herein by reference.

### FIELD

The present disclosure relates to a communication apparatus.

### BACKGROUND

WO 2018/066578 A discloses a filter that is used in a communication device that performs differential transmission on a balanced track and can reduce the influence of electrostatic noise.

In WO 2018/066578 A, a protection circuit is formed by inserting an inductor (coil) in series between a Zener diode and the GND in order to easily release a signal generated by electrostatic noise to a ground (hereinafter, also referred to as the GND), for example, in order to match with a protection component configured with the Zener diode.

However, a high-frequency component of the electrostatic noise may reach the protected component through the GND. In addition, the low-frequency component of the electrostatic noise may increase the current flowing through an impedance component. Therefore, it is desired to realize a filter having a higher noise reduction effect.

### SUMMARY

A communication device according to the present disclosure transmits a high-frequency signal. the communication device includes at least one signal line, at least one overvoltage protection component, and at least one impedance component. The at least one signal line transmits the high-frequency signal and includes a first signal line. The at least one overvoltage protection component is connected to the first signal line and includes a first overvoltage protection component. The at least one impedance component is connected in series with the first overvoltage protection component between the first signal line and a ground. The at least one impedance component achieves both reduction of current wraparound via the ground due to a high-frequency component of an electrostatic noise applied to the communication device and reduction of a current flowing through the first overvoltage protection component due to a low-frequency component of the electrostatic noise.

### BRIEF DESCRIPTION OF THE DRAWINGS

FIG. 1 is a block diagram illustrating an example of a schematic configuration of a communication device according to a first embodiment;

FIG. 2 is a current waveform illustrating an example of an electrostatic noise;

FIG. 3 is a graph illustrating an example of a voltage-current characteristic of an overvoltage protection component;

FIG. 4 is a diagram illustrating an example of a current waveform flowing through a protected component due to a first peak and a second peak of an electrostatic noise;

FIG. 5 is a diagram illustrating an example of a current waveform flowing through the protected component due to the first peak of the electrostatic noise;

FIG. 6 is a diagram illustrating a first configuration example of a communication device of a first embodiment;

FIG. 7 is a diagram illustrating an example of a simulation result of a signal passing characteristic of a protection circuit in the communication device of FIG. 6;

FIG. 8 is a diagram illustrating an example of a simulation result of an impedance of the protection circuit in the communication device of FIG. 6;

FIG. 9 is a diagram illustrating a second configuration example of the communication device of the first embodiment;

FIG. 10 is a diagram illustrating a third configuration example of the communication device of the first embodiment;

FIG. 11 is a diagram illustrating a fourth configuration example of the communication device of the first embodiment;

FIG. 12 is a diagram illustrating a fifth configuration example of the communication device of the first embodiment;

FIG. 13 is a diagram illustrating a sixth configuration example of the communication device of the first embodiment;

FIG. 14 is a diagram illustrating a seventh configuration example of the communication device of the first embodiment;

FIG. 15 is a diagram illustrating an eighth configuration example of the communication device of the first embodiment;

FIG. 16 is a diagram illustrating a ninth configuration example of the communication device of the first embodiment;

FIG. 17 is a diagram illustrating a tenth configuration example of the communication device of the first embodiment;

FIG. 18 is a diagram illustrating an eleventh configuration example of the communication device of the first embodiment;

FIG. 19 is a diagram illustrating a first configuration example of a communication device of a second embodiment;

FIG. 20 is a diagram illustrating a second configuration example of the communication device of the second embodiment;

FIG. 21 is a diagram illustrating a third configuration example of the communication device of the second embodiment;

FIG. 22 is a diagram illustrating a fourth configuration example of the communication device of the second embodiment;

FIG. 23 is a diagram illustrating a fifth configuration example of the communication device of the second embodiment; and

FIG. 24 is a diagram illustrating a sixth configuration example of the communication device of the second embodiment.

### DETAILED DESCRIPTION

### First Embodiment

Hereinafter, a first embodiment of a communication device according to the present disclosure is described with reference to the drawings.

### Schematic Configuration of Communication Device

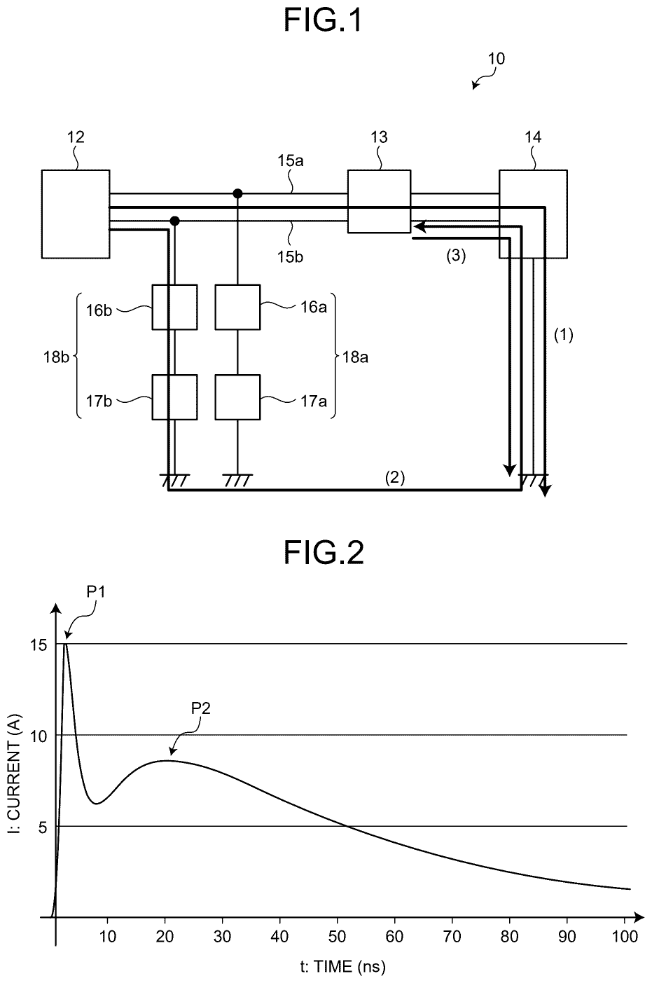

A schematic configuration of a communication device 10 according to a first embodiment is described with reference to FIG. 1. FIG. 1 is a block diagram illustrating an example of a schematic configuration of the communication device according to a first embodiment.

The communication device 10 is built in an electronic control unit (ECU) and performs information communication by differential transmission between a plurality of different ECUs. The differential transmission is a method of causing currents having phases opposite to each other to flow using two signal lines to transmit a signal due to a potential difference between the two signal lines. The communication device 10 may perform information communication, for example, with a sensor.

The communication device 10 has a structure in which a connector 12, a common mode choke coil (CMCC) 13, and a protected component 14 illustrated in FIG. 1 are connected to each other by a first signal line 15a and a second signal line 15b. Furthermore, the communication device 10 includes a first protection circuit 18a between the first signal line 15a and the ground (hereinafter, also referred to as GND). Furthermore, the communication device 10 includes a second protection circuit 18b between the second signal line 15b and the GND.

The connector 12 connects a signal source such as an ECU in a preceding stage and the communication device 10.

The CMCC 13 is a filter that removes a common mode noise. The CMCC 13 removes a noise applied in the same phase to a signal flowing through the first signal line 15a and a signal flowing through the second signal line 15b, that is, the common mode noise. Note that CMCC 13 has no influence on a signal flowing through the first signal line 15a and a signal flowing through the second signal line 15b, that is, a signal having an opposite phase. The CMCC 13 has, for example, a structure in which two conductive wires are wound around one core in opposite directions.

The protected component 14 is, for example, a component having a receiver function of converting two differentially transmitted signals into one signal, a driver function of generating two signals of opposite phases related to differential transmission, and the like.

High-frequency signals having phases opposite to each other flow through the first signal line 15a and the second signal line 15b.

The first protection circuit 18a includes a first overvoltage protection component 16a and a first impedance component 17a. Also, the second protection circuit 18b includes a second overvoltage protection component 16b and a second impedance component 17b. Note that, in the following description, when being not distinguished from each other, the first impedance component 17a and the second impedance component 17b are collectively referred to simply as impedance components 17.

The first overvoltage protection component 16a and the second overvoltage protection component 16b are components that protect the communication device 10 from electrostatic discharge (ESD) applied to the communication device 10. The first overvoltage protection component 16a and the second overvoltage protection component 16b are, for example, an ESD suppressor, a thyristor, or a TVS diode. Note that in the following description, when being not distinguished from each other, the first overvoltage protection component 16a and the second overvoltage protection component 16b are collectively referred to simply as overvoltage protection components 16.

The first impedance component 17a is inserted in series with the first overvoltage protection component 16a to release electrostatic discharge to the GND. Also, the second impedance component 17b is inserted in series with the second overvoltage protection component 16b to release electrostatic discharge to the GND. In the communication device 10 of the present embodiment, a resistive or inductive component is used for the first impedance component 17a and the second impedance component 17b. The inductive component is, for example, an inductor, a coil, beads, or a common mode noise filter. The beads are, for example, chip beads or ferrite beads. The common mode noise filter is, for example, a common mode choke coil. Note that the first impedance component 17a and the second impedance component 17b may be resistors.

### Waveform of Electrostatic Noise

A waveform of a typical electrostatic noise is described with reference to FIG. 2. FIG. 2 is a current waveform illustrating an example of the electrostatic noise.

For example, as illustrated in FIG. 2, the electrostatic noise has a first peak P1 having a very high rising speed (1 ns or less) and a slightly gentle second peak P2 following the first peak P1. The communication device 10 is required to operate normally even when electrostatic noise as illustrated in FIG. 2 is applied.

### Voltage-Current Characteristic of Overvoltage Protection Component

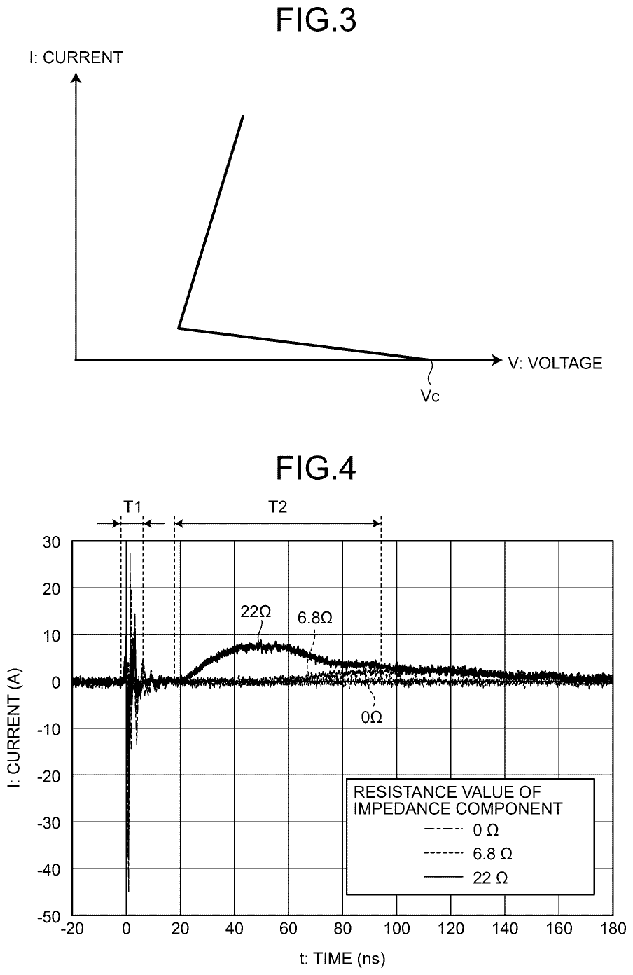

The voltage-current characteristic of the overvoltage protection component 16 is described with reference to FIG. 3. FIG. 3 is a graph illustrating an example of the voltage-current characteristic of the overvoltage protection component.

For example, an ESD suppressor used in the overvoltage protection component 16 protects the protected component 14 by allowing a normal signal to flow as it is to the protected component 14 and releasing the electrostatic noise as illustrated in FIG. 2 to the GND.

The ESD suppressor is usually an insulating component having a very high resistance value. However, as illustrated in FIG. 3, when a high voltage exceeding a predetermined voltage value Vc (for example, several hundred V) is applied, the resistance value rapidly decreases, and a current flows with a voltage drop. By using such electrical characteristics, the ESD suppressor ensures the quality of a signal flowing through a signal line when no electrostatic noise is applied and releases the electrostatic noise to the GND when the electrostatic noise is applied, thereby protecting an electronic component such as the protected component 14 or an electronic device.

### Current Flowing Through Overvoltage Protection Component When Electrostatic Noise is Applied

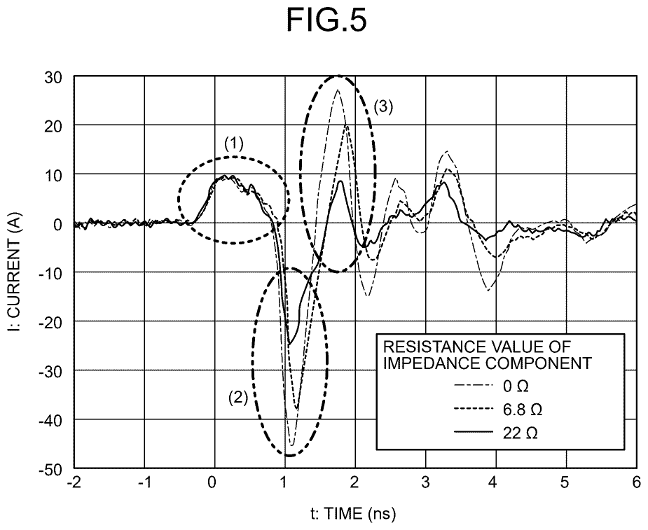

With reference to FIGS. 4 and 5, a current waveform flowing through the protected component 14 when the electrostatic noise is applied to the communication device 10 is described. FIG. 4 is a diagram illustrating an example of a current waveform flowing through the protected component 14 due to a first peak and a second peak of the electrostatic noise. FIG. 5 is a diagram illustrating an example of a current waveform flowing through the protected component 14 due to the first peak of the electrostatic noise.

FIG. 5 is an enlarged view of a portion of a time section T1 in FIG. 4. The time section T1 is a section related to the main discharge of the electrostatic noise illustrated in FIG. 2, that is, the first peak P1. On the other hand, a time section T2 illustrated in FIG. 4 is a section related to the second peak P2 followed by the main discharge of the electrostatic noise.

Prior to the main discharge, the current illustrated in (1) of FIG. 5 flows through the portion of (1) of FIG. 1 due to the capacitance of the CMCC 13. In other words, a current that reaches the ground from the connector 12 via the CMCC 13 and the protected component 14 flows. This current does not depend on the resistor constant since it is before the main discharge.

The main discharge flows to a protection circuit 18 including the overvoltage protection component 16. The GND of the protection circuit 18 and the GND of the protected component 14 are connected by a substrate GND, but there is a potential difference, so that the current illustrated in (2) of FIG. 5 flows through the portion of (2) of FIG. 1. In other words, the current that reaches the ground from the connector 12 via the protection circuit 18 flows from the ground to the protected component 14 and reaches the CMCC 13. The current (2) is partially reflected by the CMCC 13, and the current illustrated in (3) of FIG. 5 flows through the portion of (3) of FIG. 1. In other words, a current that reaches the ground from the CMCC 13 via the protected component 14 flows. The current (2) and the current (3) are damped according to the impedance of the impedance component 17 connected in series to the protection circuit 18. Therefore, the impedance component 17 contributes to protection of the protected component 14.

When the impedance component 17 such as a resistor is connected to the protection circuit 18, the effect of suppressing the current at the second peak P2 decreases. Therefore, by using, for example, beads having frequency characteristics as the impedance component 17, it is possible to reduce only the frequency component of the first peak P1 without affecting the frequency component of the second peak P2.

For example, in FIG. 5, when the resistance value of the impedance component 17 is increased, the amount of the current related to the first peak P1 of the electrostatic noise flowing through the protected component 14 can be reduced. For example, in FIG. 5, the current is smaller when the resistance value of the impedance component 17 is 6.8 Ω than 0 Ω. In addition, the current is smaller when the resistance value of the impedance component 17 is 22 Ω than 6.8 Ω.

On the other hand, in the time section T2 illustrated in FIG. 4, that is, the section related to the second peak P2 of the electrostatic noise, the amount of current flowing to the protected component 14 can be reduced when the resistance value of the impedance component 17 is smaller. For example, in the time section T2 of FIG. 4, the current is smaller when the resistance value of the impedance component 17 is 6.8 Ω than 22 Ω. Also, the current is smaller when the resistance value of the impedance component 17 is 0 Ω than 6.8 Ω.

As described above, in order to reduce the current flowing through the protected component 14 and reduce the influence of the electrostatic noise, the impedance of the impedance component 17 inserted into the protection circuit 18 is desirably as large as possible in the time section T1. In addition, the impedance of the impedance component 17 inserted into the protection circuit 18 is desirably as small as possible in the time section T2.

Here, when the typical electrostatic noise waveform illustrated in FIG. 2 is analyzed, the first peak P1 has a frequency component of several hundred MHz. Also, the second peak P2 has a frequency component of several MHz. Therefore, it is desirable that the impedance of the impedance component 17 inserted into the protection circuit 18 is as small as possible in a frequency band of several MHz and as large as possible in a frequency band of several hundred MHz.

### First Configuration Example of Communication Device of First Embodiment

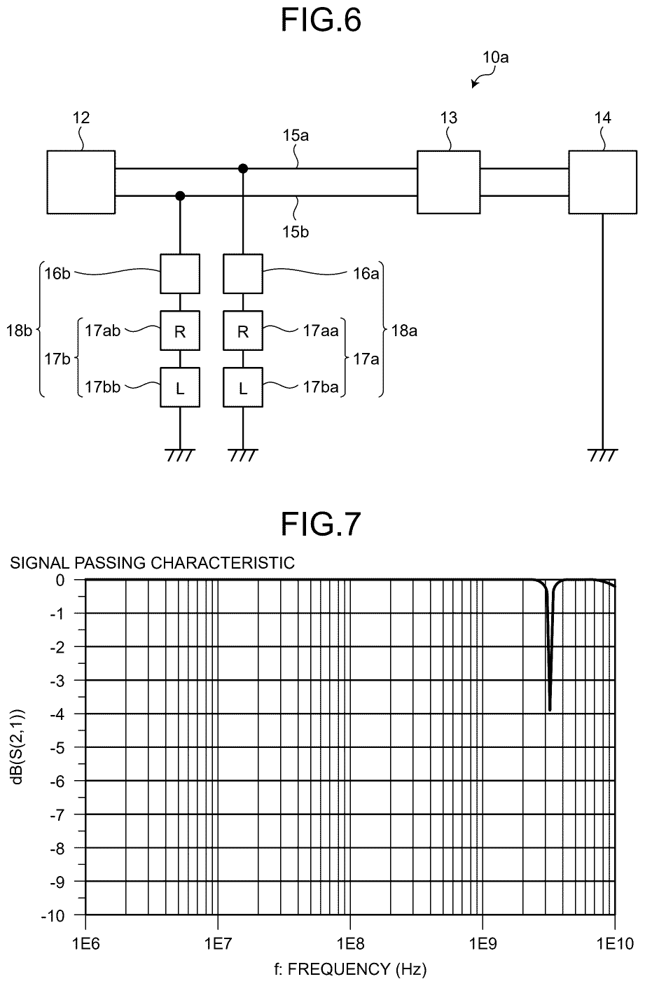

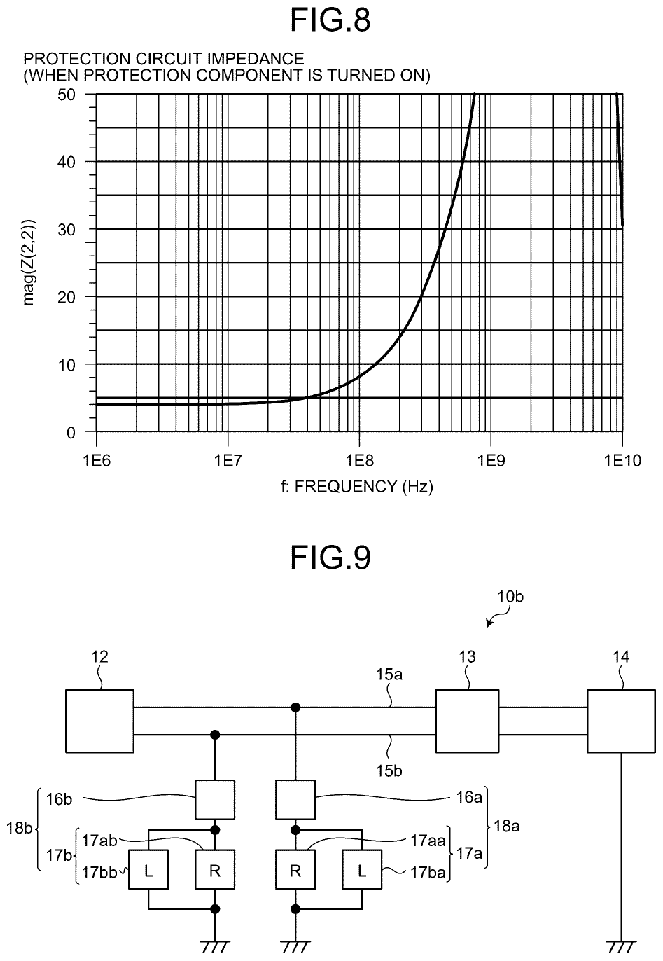

A communication device 10a as a first configuration example of the first embodiment is described with reference to FIGS. 6 to 8. FIG. 6 is a diagram illustrating a first configuration example of the communication device of the first embodiment. FIG. 7 is a diagram illustrating an example of a simulation result of a signal passing characteristic of a protection circuit in the communication device of FIG. 6. FIG. 8 is a diagram illustrating an example of the simulation result of the impedance of the protection circuit in the communication device of FIG. 6.

The communication device 10a illustrated in FIG. 6 has a structure similar to that of the communication device 10 (see FIG. 1) described above. As the first impedance component 17a, a first resistor 17aa and a first inductor 17ba are inserted in series between the first overvoltage protection component 16a connected to the first signal line 15a and the GND. As the second impedance component 17b, a second resistor 17ab and a second inductor 17bb are inserted in series between the second overvoltage protection component 16b connected to the second signal line 15b and the GND.

The inventors of the present disclosure have performed simulation of the signal passing characteristics and impedance of the first protection circuit 18a and the second protection circuit 18b for the communication device 10a in FIG. 6. Note that the first resistor 17aa and the second resistor 17ab in FIG. 6 are set to 4 Ω, and the first inductor 17ba and the second inductor 17bb are set to 10 nH.

FIG. 7 is a simulation result illustrating signal passing characteristics of the first protection circuit 18a and the second protection circuit 18b in the communication device 10a of FIG. 6. In FIG. 7, the horizontal axis represents a frequency, and the vertical axis represents a passing rate of a signal. It can be seen from FIG. 7 that the communication device 10a can transmit a signal in a frequency band up to several GHz without attenuating the signal.

FIG. 8 is a simulation result illustrating impedances of the first protection circuit 18a and the second protection circuit 18b of the communication device 10a of FIG. 6. In FIG. 8, the horizontal axis represents a frequency, and the vertical axis represents impedances of the first protection circuit 18a connected to the first signal line 15a and the second protection circuit 18b connected to the second signal line 15b when the first overvoltage protection component 16a and the second overvoltage protection component 16b are turned ON. From FIG. 8, it can be seen that the impedance of the first protection circuit 18a and the second protection circuit 18b of the communication device 10a is lower in the frequency band (several MHz) corresponding to the second peak P2 (see FIG. 2) of the electrostatic noise than in the frequency band (several hundred MHz) corresponding to the first peak P1 (see FIG. 2) of the electrostatic noise.

As described above, according to the configuration of the communication device 10a, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

### Second Configuration Example of Communication Device of First Embodiment

A communication device 10b as a second configuration example of the first embodiment is described with reference to FIG. 9. FIG. 9 is a diagram illustrating a second configuration example of the communication device of the first embodiment.

The communication device 10a illustrated in FIG. 9 has a structure similar to that of the communication device 10 (see FIG. 1) described above. As the first impedance component 17a, the first resistor 17aa and the first inductor 17ba are inserted in parallel between the first overvoltage protection component 16a connected to the first signal line 15a and the GND. As the second impedance component 17b, the second resistor 17ab and the second inductor 17bb are inserted in parallel between the second overvoltage protection component 16b connected to the second signal line 15b and the GND.

The inventors of the present disclosure have performed simulation of the signal passing characteristics and impedance of the first protection circuit 18a and the second protection circuit 18b for the communication device 10b as described above. As a result, it is confirmed that the same tendency as in FIGS. 7 and 8 was exhibited.

As described above, according to the configuration of the communication device 10b, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Third Configuration Example of Communication Device of First Embodiment

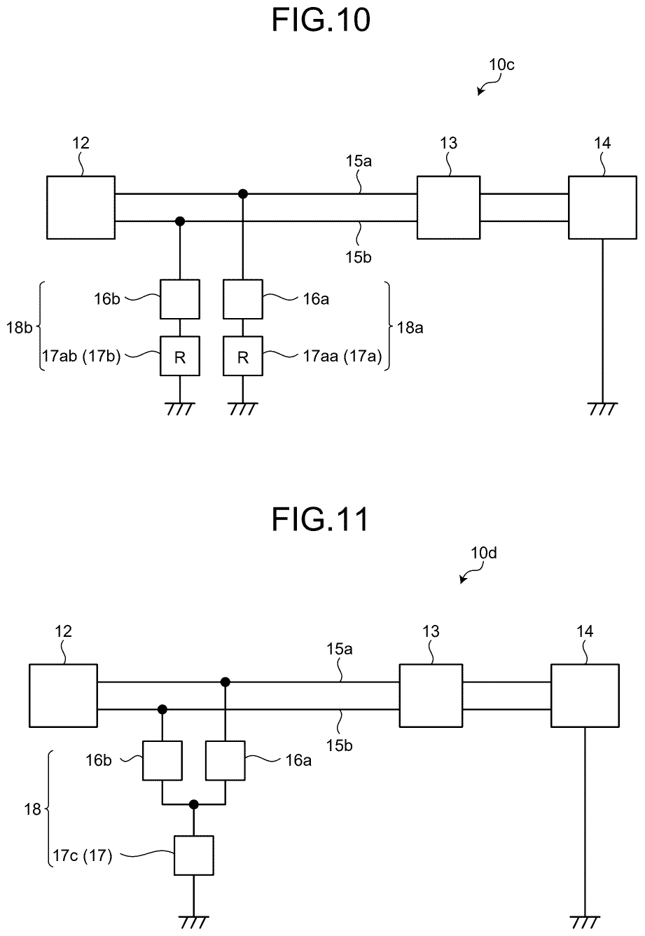

A communication device 10c as a third configuration example of the first embodiment is described with reference to FIG. 10. FIG. 10 is a diagram illustrating the third configuration example of the communication device of the first embodiment.

The communication device 10b illustrated in FIG. 10 has a structure similar to that of the communication device 10 (see FIG. 1) described above. As the first impedance component 17a, the first resistor 17aa is inserted in parallel between the first overvoltage protection component 16a connected to the first signal line 15a and the GND. Also, as the second impedance component 17b, the second resistor 17ab is inserted in parallel between the second overvoltage protection component 16b connected to the second signal line 15b and the GND.

The inventors of the present disclosure have performed simulation of the signal passing characteristics and impedance of the first protection circuit 18a and the second protection circuit 18b for the communication device 10c as described above. As a result, it is confirmed that the same tendency as in FIGS. 7 and 8 was exhibited.

As described above, according to the configuration of the communication device 10c, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Fourth Configuration Example of Communication Device of First Embodiment

A communication device 10d as a fourth configuration example of the first embodiment is described with reference to FIG. 11. FIG. 11 is a diagram illustrating the fourth configuration example of the communication device of the first embodiment.

The communication device 10d illustrated in FIG. 11 has a structure similar to that of the communication device 10 (see FIG. 1) described above. Then, a configuration in which a ferrite bead 17c is inserted as the impedance component 17 between the GND and a connection point between the first overvoltage protection component 16a connected to the first signal line 15a and the second overvoltage protection component 16b connected to the second signal line 15b is provided.

The ferrite bead 17c is also called a chip inductor or a bead inductor. Like the inductor, the ferrite bead 17c is an impedance component of which the impedance increases as the frequency increases.

The inventors of the present disclosure have performed simulation of the signal passing characteristics and impedance of the protection circuit 18 for the communication device 10d as described above. As a result, it is confirmed that the same tendency as in FIGS. 7 and 8 was exhibited.

As described above, according to the configuration of the communication device 10d, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Fifth Configuration Example of Communication Device of First Embodiment

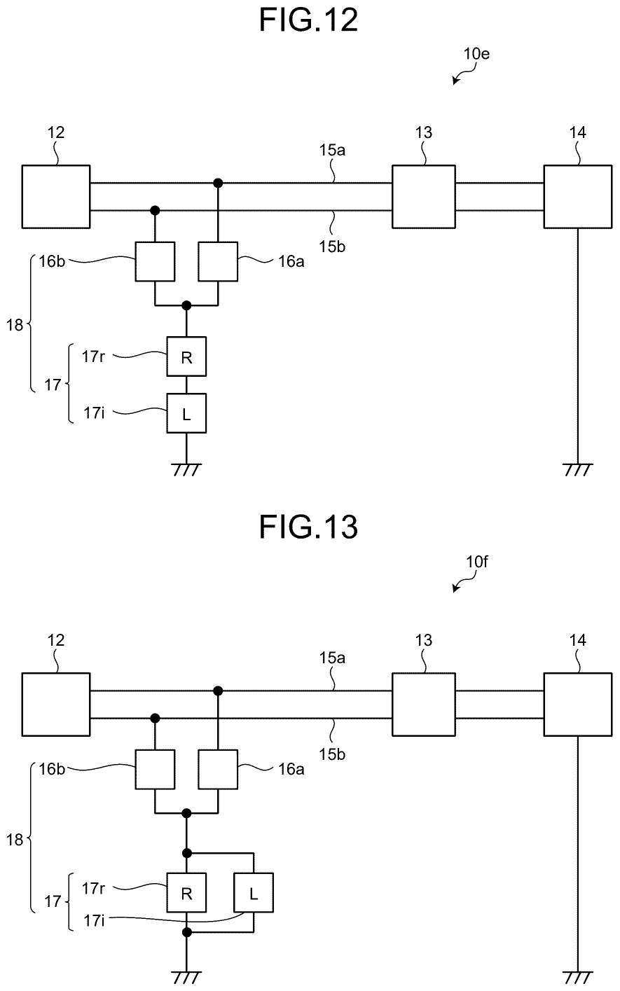

A communication device 10e as a fifth configuration example of the first embodiment is described with reference to FIG. 12. FIG. 12 is a diagram illustrating the fifth configuration example of the communication device of the first embodiment.

The communication device 10e illustrated in FIG. 12 has a structure similar to that of the communication device 10 (see FIG. 1) described above. Then, a configuration in which a resistor 17r and an inductor 17i are inserted in series as the impedance component 17 between the GND and a connection point between the first overvoltage protection component 16a connected to the first signal line 15a and the second overvoltage protection component 16b connected to the second signal line 15b is provided.

The inventors of the present disclosure have performed simulation of the signal passing characteristics and impedance of the protection circuit 18 for the communication device 10e as described above. As a result, it is confirmed that the same tendency as in FIGS. 7 and 8 was exhibited.

As described above, according to the configuration of the communication device 10e, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Sixth Configuration Example of Communication Device of First Embodiment

A communication device 10f as a sixth configuration example of the first embodiment is described with reference to FIG. 13. FIG. 13 is a diagram illustrating the sixth configuration example of the communication device of the first embodiment.

The communication device 10f illustrated in FIG. 13 has a structure similar to that of the communication device 10 (see FIG. 1) described above. Then, a configuration in which the resistor 17r and the inductor 17i are inserted in parallel as the impedance component 17 between the GND and a connection point between the first overvoltage protection component 16a connected to the first signal line 15a and the second overvoltage protection component 16b connected to the second signal line 15b is provided.

The inventors of the present disclosure have performed simulation of the signal passing characteristics and impedance of the protection circuit 18 for the communication device 10f as described above. As a result, it is confirmed that the same tendency as in FIGS. 7 and 8 was exhibited.

As described above, according to the configuration of the communication device 10f, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Seventh Configuration Example of Communication Device of First Embodiment

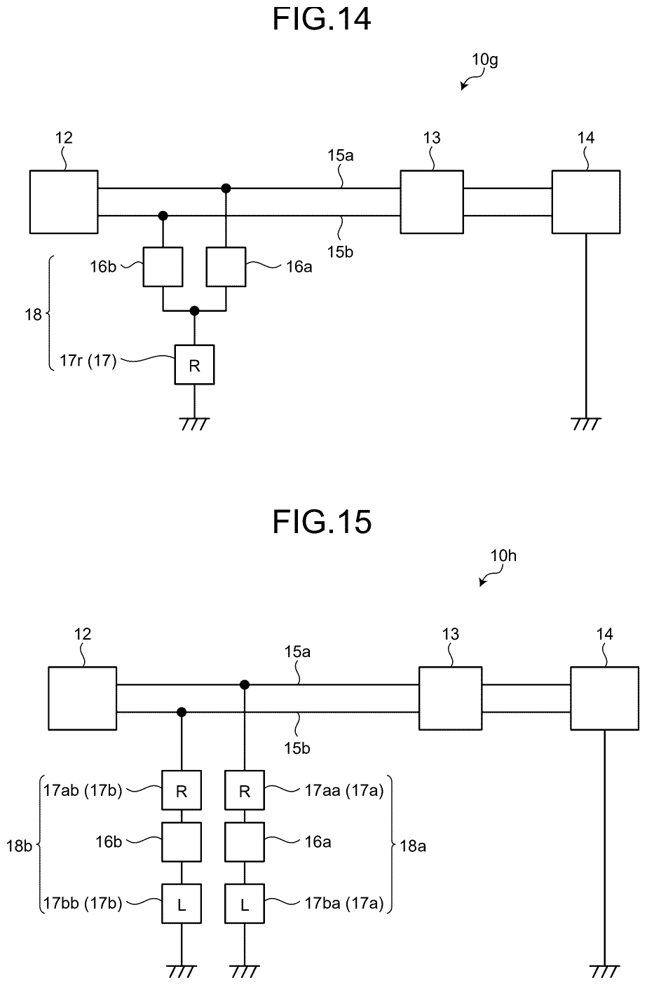

A communication device 10g as a seventh configuration example of the first embodiment is described with reference to FIG. 14. FIG. 14 is a diagram illustrating the seventh configuration example of the communication device of the first embodiment.

The communication device 10g illustrated in FIG. 14 has a structure similar to that of the communication device 10 (see FIG. 1) described above. Then, a configuration in which the resistor 17r is inserted as the impedance component 17 between the GND and a connection point between the first overvoltage protection component 16a connected to the first signal line 15a and the second overvoltage protection component 16b connected to the second signal line 15b is provided.

The inventors of the present disclosure have performed simulation of the signal passing characteristics and impedance of the protection circuit 18 for the communication device 10g as described above. As a result, it is confirmed that the same tendency as in FIGS. 7 and 8 was exhibited.

As described above, according to the configuration of the communication device 10g, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Eighth Configuration Example of Communication Device of First Embodiment

A communication device 10h as an eighth configuration example of the first embodiment is described with reference to FIG. 15. FIG. 15 is a diagram illustrating the eighth configuration example of the communication device of the first embodiment.

The communication device 10h illustrated in FIG. 15 has a structure similar to that of the communication device 10 (see FIG. 1) described above. Specifically, the communication device 10h includes the first protection circuit 18a between the first signal line 15a and the GND. The first protection circuit 18a includes a first overvoltage protection component 16a and a first impedance component 17a. As the first impedance component 17a, the first resistor 17aa is inserted on the preceding stage side of the first overvoltage protection component 16a, that is, on the first signal line 15a side, and the first inductor 17ba is inserted between the first overvoltage protection component 16a and the GND. Furthermore, the communication device 10h includes the second protection circuit 18b between the second signal line 15b and the GND. The second protection circuit 18b includes a second overvoltage protection component 16b and a second impedance component 17b. As the second impedance component 17b, the second resistor 17ab is inserted on the preceding stage side of the second overvoltage protection component 16b, that is, the second signal line 15b side, and the second inductor 17bb is inserted between the second overvoltage protection component 16b and the GND.

The inventors of the present disclosure have performed simulation of the signal passing characteristics and impedance of the first protection circuit 18a and the second protection circuit 18b for the communication device 10h as described above. As a result, it is confirmed that the same tendency as in FIGS. 7 and 8 was exhibited.

As described above, according to the configuration of the communication device 10h, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Ninth Configuration Example of Communication Device of First Embodiment

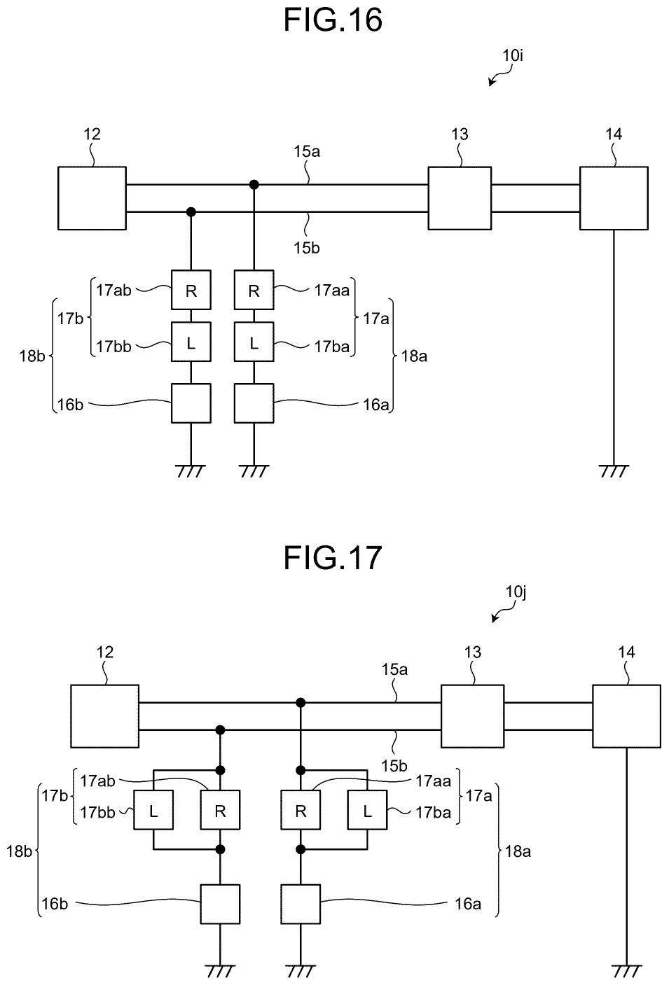

A communication device 10i as a ninth configuration example of the first embodiment is described with reference to FIG. 16. FIG. 16 is a diagram illustrating the ninth configuration example of the communication device of the first embodiment.

The communication device 10i illustrated in FIG. 16 has a structure similar to that of the communication device 10 (see FIG. 1) described above. Specifically, the communication device 10i includes the first protection circuit 18a between the first signal line 15a and the GND. The first protection circuit 18a includes a first overvoltage protection component 16a and a first impedance component 17a. As the first impedance component 17a, the first resistor 17aa and the first inductor 17ba are inserted in series on the preceding stage side of the first overvoltage protection component 16a connected to the first signal line 15a. Furthermore, the communication device 10i includes the second protection circuit 18b between the second signal line 15b and the GND. The second protection circuit 18b includes a second overvoltage protection component 16b and a second impedance component 17b. As the second impedance component 17b, the second resistor 17ab and the second inductor 17bb are inserted in series on the preceding stage side of the second overvoltage protection component 16b.

The inventors of the present disclosure have performed simulation of the signal passing characteristics and impedance of the first protection circuit 18a and the second protection circuit 18b for the communication device 10i as described above. As a result, it is confirmed that the same tendency as in FIGS. 7 and 8 was exhibited.

As described above, according to the configuration of the communication device 10i, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Tenth Configuration Example of Communication Device of First Embodiment

A communication device 10j as a tenth configuration example of the first embodiment is described with reference to FIG. 17. FIG. 17 is a diagram illustrating the tenth configuration example of the communication device of the first embodiment.

The communication device 10j illustrated in FIG. 17 has a structure similar to that of the communication device 10 (see FIG. 1) described above. Specifically, the communication device 10j includes the first protection circuit 18a between the first signal line 15a and the GND. The first protection circuit 18a includes a first overvoltage protection component 16a and a first impedance component 17a. As the first impedance component 17a, the first resistor 17aa and the first inductor 17ba are inserted in parallel on the preceding stage side of the first overvoltage protection component 16a. Furthermore, the communication device 10j includes the second protection circuit 18b between the second signal line 15b and the GND. The second protection circuit 18b includes a second overvoltage protection component 16b and a second impedance component 17b. As the second impedance component 17b, the second resistor 17ab and the second inductor 17bb are inserted in parallel on the preceding stage side of the second overvoltage protection component 16b.

The inventors of the present disclosure have performed simulation of the signal passing characteristics and impedance of the first protection circuit 18a and the second protection circuit 18b for the communication device 10j as described above. As a result, it is confirmed that the same tendency as in FIGS. 7 and 8 was exhibited.

As described above, according to the configuration of the communication device 10j, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Eleventh Configuration Example of Communication Device of First Embodiment

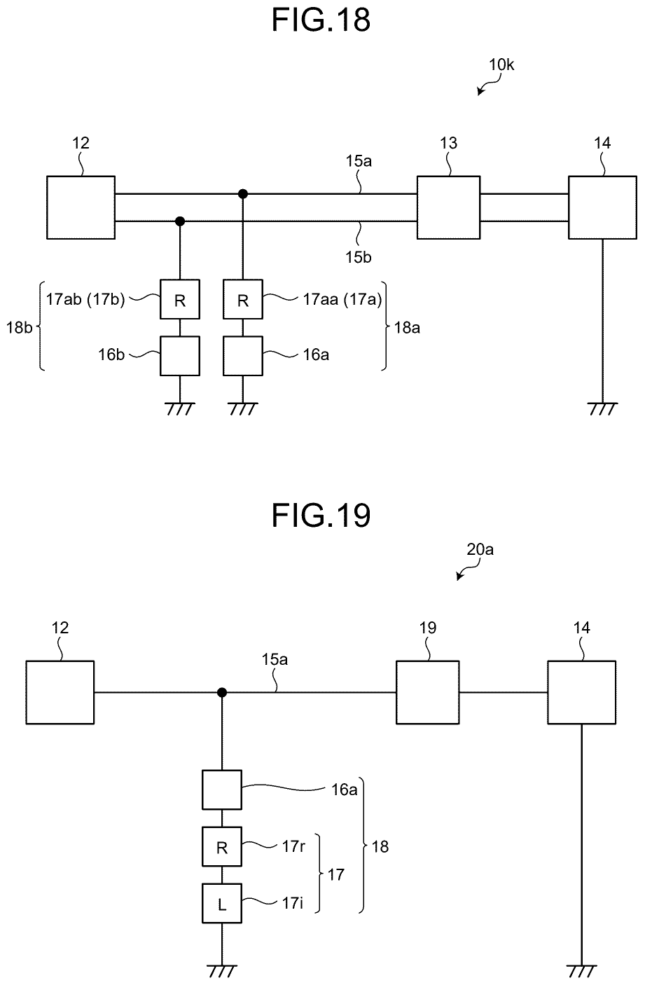

A communication device 10k as an eleventh configuration example of the first embodiment is described with reference to FIG. 18. FIG. 18 is a diagram illustrating the eleventh configuration example of the communication device of the first embodiment.

The communication device 10k illustrated in FIG. 18 has a structure similar to that of the communication device 10 (see FIG. 1) described above. Specifically, the communication device 10k includes the first protection circuit 18a between the first signal line 15a and the GND. The first protection circuit 18a includes a first overvoltage protection component 16a and a first impedance component 17a. As the first impedance component 17a, the first resistor 17aa is inserted on the preceding stage side of the first overvoltage protection component 16a. Furthermore, the communication device 10k includes the second protection circuit 18b between the second signal line 15b and the GND. The second protection circuit 18b includes a second overvoltage protection component 16b and a second impedance component 17b. As the second impedance component 17b, the second resistor 17ab is inserted on the preceding stage side of the second overvoltage protection component 16b.

The inventors of the present disclosure have performed simulation of the signal passing characteristics and impedance of the first protection circuit 18a and the second protection circuit 18b for the communication device 10k as described above. As a result, it is confirmed that the same tendency as in FIGS. 7 and 8 was exhibited.

As described above, according to the configuration of the communication device 10k, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Operation and Effect of First Embodiment

As described above, the communication device 10a according to the first embodiment is a communication device that transmits a high-frequency signal, and includes at least one signal line that transmits a high-frequency signal and includes the first signal line 15a; at least one overvoltage protection component that is connected to the first signal line 15a and includes the first overvoltage protection component 16a; and at least one impedance component 17 that is connected in series with the first overvoltage protection component 16a between the first signal line 15a and the ground. The at least one impedance component 17 achieves both reduction of current wraparound via the ground due to a high-frequency component of an electrostatic noise applied to the communication device 10a and reduction of the current flowing through the first overvoltage protection component 16a due to a low-frequency component of the electrostatic noise. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

Furthermore, in the communication device 10a according to the first embodiment, the at least one signal line further includes the second signal line 15b and at least one overvoltage protection component that is connected to the second signal line 15b and includes the second overvoltage protection component 16b, and the high-frequency signal is transmitted by differential transmission by the first signal line 15a and the second signal line 15b. Therefore, when differential transmission is performed, the influence of the electrostatic noise applied to the communication device 10a can be reduced.

In addition, in the communication device 10a according to the first embodiment, the at least one impedance component 17 includes the first resistor 17aa and the first inductor 17ba that are inserted in series between the first overvoltage protection component 16a and the ground, and the second resistor 17ab and the second inductor 17bb that are inserted in series between the second overvoltage protection component 16b and the ground. As a result, since the impedance in the frequency band of several MHz of the first protection circuit 18a and the second protection circuit 18b is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10b according to the first embodiment, the at least one impedance component 17 is the first resistor 17aa and the first inductor 17ba that are inserted in parallel between the first overvoltage protection component 16a and the ground, and the second resistor 17ab and the second inductor 17bb that are inserted in parallel between the second overvoltage protection component 16b and the ground. As a result, since the impedance in the frequency band of several MHz of the first protection circuit 18a and the second protection circuit 18b is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10c according to the first embodiment, the at least one impedance component 17 is the first resistor 17aa that is inserted between the first overvoltage protection component 16a and the ground, and the second resistor 17ab that is inserted between the second overvoltage protection component 16b and the ground. As a result, since the impedance in the frequency band of several MHz of the first protection circuit 18a and the second protection circuit 18b is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10d according to the first embodiment, the at least one impedance component 17 is the ferrite bead 17c that is inserted between the ground and a connection point between the first overvoltage protection component 16a and the second overvoltage protection component 16b. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10e according to the first embodiment, the at least one impedance component 17 is the resistor 17r and the inductor 17i that are inserted in series between the ground and a connection point between the first overvoltage protection component 16a and the second overvoltage protection component 16b. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10f according to the first embodiment, the at least one impedance component 17 is the resistor 17r and the inductor 17i that are inserted in parallel between the ground and a connection point between the first overvoltage protection component 16a and the second overvoltage protection component 16b. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10g according to the first embodiment, the at least one impedance component 17 is the resistor 17r that is inserted between the ground and a connection point between the first overvoltage protection component 16a and the second overvoltage protection component 16b. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10h according to the first embodiment, the at least one impedance component 17 includes the first resistor 17aa that is inserted on the preceding stage side of the first overvoltage protection component 16a, the first inductor 17ba that is inserted between the first overvoltage protection component 16a and the ground, the second resistor 17ab that is inserted on the preceding stage side of the second overvoltage protection component 16b, and the second inductor 17bb that is inserted between the second overvoltage protection component 16b and the ground. As a result, since the impedance in the frequency band of several MHz of the first protection circuit 18a and the second protection circuit 18b is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10i according to the first embodiment, the at least one impedance component 17 includes the first resistor 17aa and the first inductor 17ba that are inserted in series on the preceding stage side of the first overvoltage protection component 16a, and the second resistor 17ab and the second inductor 17bb that are inserted in series on the preceding stage side of the second overvoltage protection component 16b. As a result, since the impedance in the frequency band of several MHz of the first protection circuit 18a and the second protection circuit 18b is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10j according to the first embodiment, the at least one impedance component 17 includes the first resistor 17aa and the first inductor 17ba that are inserted in parallel on the preceding stage side of the first overvoltage protection component 16a, and the second resistor 17ab and the second inductor 17bb that are inserted in parallel on the preceding stage side of the second overvoltage protection component 16b. As a result, since the impedance in the frequency band of several MHz of the first protection circuit 18a and the second protection circuit 18b is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 10k according to the first embodiment, the at least one impedance component 17 includes the first resistor 17aa that is inserted on the preceding stage side of the first overvoltage protection component 16a and the second resistor 17ab each that is inserted on the preceding stage side of the second overvoltage protection component 16b. As a result, since the impedance in the frequency band of several MHz of the first protection circuit 18a and the second protection circuit 18b is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication devices 10a to 10k according to the first embodiment, the first overvoltage protection component 16a and the second overvoltage protection component 16b are ESD suppressors or thyristors. Therefore, when the electrostatic noise is applied to the first protection circuit 18a and the second protection circuit 18b, it is possible to protect the electronic device such as the protected component 14 by releasing the electrostatic noise to the ground.

### Second Embodiment

Hereinafter, a second embodiment of a communication device according to the present disclosure is described with reference to the drawings.

### First Configuration Example of Communication Device of Second Embodiment

A communication device 20a illustrated in FIG. 19 transmits a high-frequency signal through the one first signal line 15a (single transmission). The communication device 20a has a structure in which the connector 12, the CMCC 13, and the protected component 14 are connected to each other via the first signal line 15a. Furthermore, the communication device 20a includes the protection circuit 18 between the first signal line 15a and the ground (hereinafter, also referred to as the GND).

The connector 12, the CMCC 13, and the protected component 14 are as described in the first embodiment. Also, the communication device 20a includes the first overvoltage protection component 16a and the impedance component 17 in the protection circuit 18.

The first overvoltage protection component 16a is as described in the first embodiment.

The impedance component 17 has a configuration in which the resistor 17r and the inductor 17i are connected in series.

The inventors of the present disclosure have performed simulation of the signal passing characteristics and impedance of the protection circuit 18 for the communication device 20a as described above. As a result, it is confirmed that the same tendency as in FIGS. 7 and 8 was exhibited.

As described above, according to the configuration of the communication device 20a, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Second Configuration Example of Communication Device of Second Embodiment

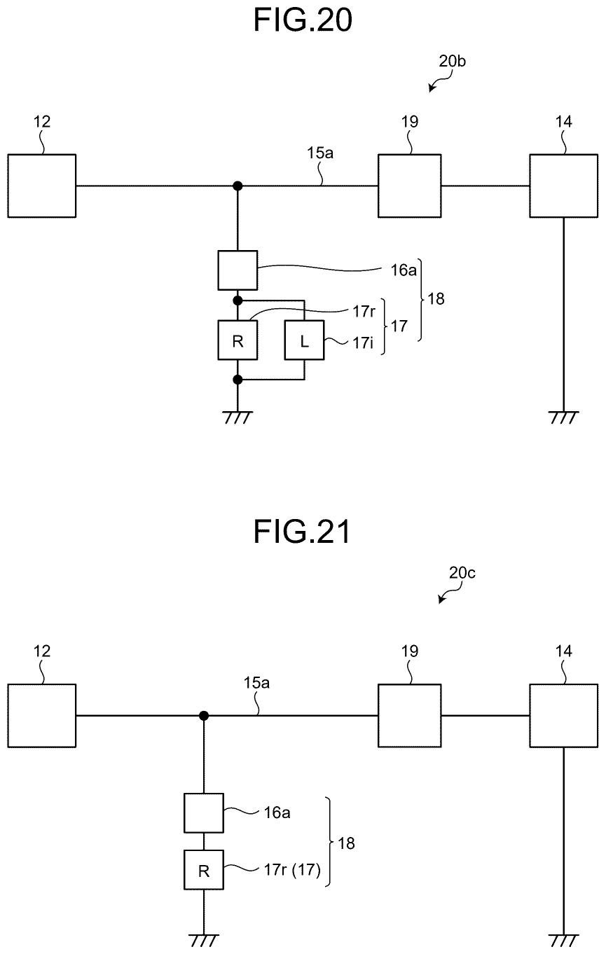

A communication device 20b as a second configuration example of the first embodiment is described with reference to FIG. 20. FIG. 20 is a diagram illustrating the second configuration example of the communication device of the second embodiment.

The communication device 20b illustrated in FIG. 20 has a structure similar to that of the communication device 20a described above. Also, a configuration in which the resistor 17r and the inductor 17i are inserted in parallel between the first overvoltage protection component 16a and the GND as the impedance component 17 is provided.

The inventors of the present disclosure have performed simulation of the signal passing characteristics and impedance of the protection circuit 18 for the communication device 20b as described above. As a result, it is confirmed that the same tendency as in FIGS. 7 and 8 was exhibited.

As described above, according to the configuration of the communication device 20b, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Third Configuration Example of Communication Device of Second Embodiment

A communication device 20c as the second configuration example of the first embodiment is described with reference to FIG. 21. FIG. 21 is a diagram illustrating a third configuration example of the communication device of the second embodiment.

The communication device 20c illustrated in FIG. 21 has a structure similar to that of the communication device 20a described above. Also, a configuration in which the resistor 17r is inserted between the first overvoltage protection component 16a and the GND as the impedance component 17 is provided.

The inventors of the present disclosure have performed simulation of the signal passing characteristics and impedance of the protection circuit 18 for the communication device 20c as described above. As a result, it is confirmed that the same tendency as in FIGS. 7 and 8 was exhibited.

As described above, according to the configuration of the communication device 20c, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Fourth Configuration Example of Communication Device of Second Embodiment

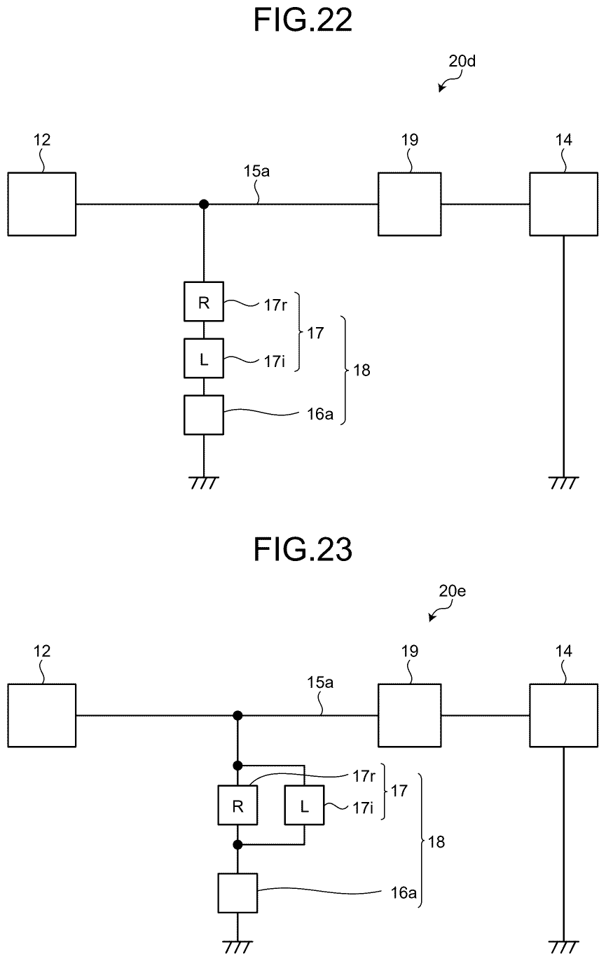

A communication device 20d as the second configuration example of the first embodiment is described with reference to FIG. 22. FIG. 22 is a diagram illustrating a fourth configuration example of the communication device of the second embodiment.

The communication device 20d illustrated in FIG. 22 has a structure similar to that of the communication device 20a described above. Also, a configuration in which the resistor 17r and the inductor 17i are inserted in series on the preceding stage side of the first overvoltage protection component 16a as the impedance component 17 is provided.

The inventors of the present disclosure have performed simulation of the signal passing characteristics and impedance of the protection circuit 18 for the communication device 20d as described above. As a result, it is confirmed that the same tendency as in FIGS. 7 and 8 was exhibited.

As described above, according to the configuration of the communication device 20d, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Fifth Configuration Example of Communication Device of Second Embodiment

A communication device 20e as the second configuration example of the first embodiment is described with reference to FIG. 23. FIG. 23 is a diagram illustrating a fifth configuration example of the communication device of the second embodiment.

The communication device 20e illustrated in FIG. 23 has a structure similar to that of the communication device 20a described above. Also, a configuration in which the resistor 17r and the inductor 17i are inserted in parallel on the preceding stage side of the first overvoltage protection component 16a as the impedance component 17 is provided.

The inventors of the present disclosure have performed simulation of the signal passing characteristics and impedance of the protection circuit 18 for the communication device 20e as described above. As a result, it is confirmed that the same tendency as in FIGS. 7 and 8 was exhibited.

As described above, according to the configuration of the communication device 20e, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Sixth Configuration Example of Communication Device of Second Embodiment

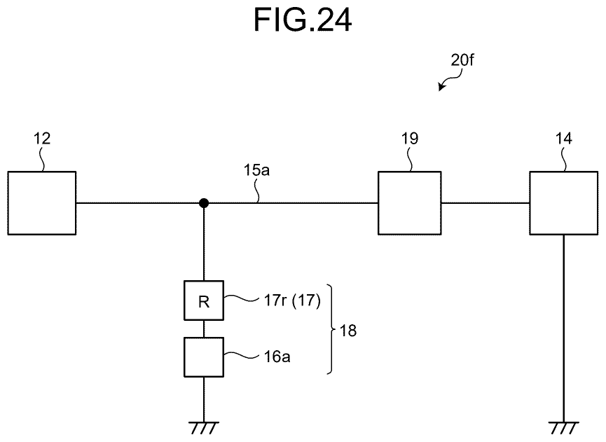

A communication device 20f as the second configuration example of the first embodiment is described with reference to FIG. 24. FIG. 24 is a diagram illustrating a sixth configuration example of the communication device of the second embodiment.

The communication device 20f illustrated in FIG. 24 has a structure similar to that of the communication device 20a described above. Also, a configuration in which the resistor 17r is inserted on the preceding stage side of the first overvoltage protection component 16a as the impedance component 17 is provided.

The inventors of the present disclosure have performed simulation of the signal passing characteristics and impedance of the protection circuit 18 for the communication device 20f as described above. As a result, it is confirmed that the same tendency as in FIGS. 7 and 8 was exhibited.

As described above, according to the configuration of the communication device 20f, since the impedance in the frequency band of several MHz of the protection circuit 18 is smaller than the impedance in the frequency band of several hundred MHz, it is possible to reduce both the influences of the first peak P1 and the second peak P2 of the electrostatic noise.

### Operation and Effect of Second Embodiment

As described above, in the communication device 20a according to the second embodiment, the high-frequency signal is transmitted by single transmission by the first signal line 15a. Therefore, when single transmission is performed, the influence of the electrostatic noise applied to the communication device 10a can be reduced.

In addition, in the communication device 20a according to the second embodiment, the impedance component 17 is the resistor 17r and the inductor 17i that are inserted in series between the first overvoltage protection component 16a and the ground. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 20b according to the second embodiment, the impedance component 17 is the resistor 17r and the inductor 17i that are inserted in parallel between the first overvoltage protection component 16a and the ground. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 20c according to the second embodiment, the impedance component 17 is the resistor 17r that is inserted in parallel between the first overvoltage protection component 16a and the ground. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 20d according to the second embodiment, the impedance component 17 is the resistor 17r and the inductor 17i that are inserted in series between the first signal line 15a and the first overvoltage protection component 16a. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication device 20e according to the second embodiment, the impedance component 17 is the resistor 17r and the inductor 17i that are inserted in parallel between the first signal line 15a and the first overvoltage protection component 16a. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHZ of the electrostatic noise.

In addition, in the communication device 20f according to the second embodiment, the impedance component 17 is the resistor 17r that is inserted between the first signal line 15a and the first overvoltage protection component 16a. As a result, since the impedance in the frequency band of several MHz of the protection circuit 18 is smaller than the impedance in the frequency band of several hundred MHz, it is possible to reduce both the influence of the first peak P1 having the frequency band of several hundred MHz and the influence of the second peak P2 having the frequency band of several MHz of the electrostatic noise.

In addition, in the communication devices 20a to 20f according to the second embodiment, the first overvoltage protection component 16a is an ESD suppressor or a thyristor. Therefore, when the electrostatic noise is applied to the protection circuit 18, it is possible to protect the electronic device such as the protected component 14 by releasing the electrostatic noise to the ground.

### Supplement

The following items are described by the above description of the embodiments.

(Item 1) A communication device that transmits a high-frequency signal, including: at least one signal line that transmits the high-frequency signal and includes a first signal line; at least one overvoltage protection component that is connected to the first signal line and includes a first overvoltage protection component; and at least one impedance component that is connected in series with the first overvoltage protection component between the first signal line and a ground, in which the at least one impedance component achieves both reduction of current wraparound via the ground due to a high-frequency component of an electrostatic noise applied to the communication device and reduction of a current flowing through the first overvoltage protection component due to a low-frequency component of the electrostatic noise.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 2) The communication device according to Item 1, in which the at least one signal line further includes: a second signal line; and at least one overvoltage protection component that is connected to the second signal line and includes a second overvoltage protection component, and the high-frequency signal is transmitted by differential transmission by the first signal line and the second signal line.

With this configuration, when differential

transmission is performed, the influence of the electrostatic noise applied to the communication device can be reduced.

(Item 3) The communication device according to Item 2, in which the at least one impedance component includes a first resistor and a first inductor that are inserted in series between the first overvoltage protection component and the ground, and a second resistor and a second inductor that are inserted in series between the second overvoltage protection component and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 4) The communication device according to Item 2, in which the at least one impedance component includes a first resistor and a first inductor that are inserted in parallel between the first overvoltage protection component and the ground, and a second resistor and a second inductor that are inserted in parallel between the second overvoltage protection component and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 5) The communication device according to Item 2, in which the at least one impedance component includes a first resistor that is inserted between the first overvoltage protection component and the ground, and a second resistor that is inserted between the second overvoltage protection component and the ground.

With this configuration, since the impedance in the frequency band of several MHz of the protection circuit is smaller than the impedance in the frequency band of several hundred MHz, it is possible to reduce both the influence of the first peak having the frequency band of several hundred

MHz and the influence of the second peak having the frequency band of several MHz of the electrostatic noise.

(Item 6) The communication device according to Item 2, in which the at least one impedance component is a ferrite bead that is inserted between a connection point between the first overvoltage protection component and the second overvoltage protection component, and the ground. With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 7) The communication device according to Item 2, in which the at least one impedance component includes a resistor and an inductor that are inserted in series between a connection point between the first overvoltage protection component and the second overvoltage protection component, and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 8) The communication device according to Item 2, in which the at least one impedance component includes a resistor and an inductor that are inserted in parallel between a connection point between the first overvoltage protection component and the second overvoltage protection component, and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 9) The communication device according to Item 2, in which the at least one impedance component is a resistor that is inserted between a connection point between the first overvoltage protection component and the second overvoltage protection component, and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 10) The communication device according to Item 2, in which the at least one impedance component includes a first resistor that is inserted on a preceding stage side of the first overvoltage protection component, a first inductor that is inserted between the first overvoltage protection component and the ground, a second resistor that is inserted on a preceding stage side of the second overvoltage protection component, and a second inductor that is inserted between the second overvoltage protection component and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 11) The communication device according to Item 2, in which the at least one impedance component includes a first resistor and a first inductor that are inserted in series on a preceding stage side of the first overvoltage protection component, and a second resistor and a second inductor that are inserted in series on a preceding stage side of the second overvoltage protection component.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 12) The communication device according to Item 2, in which the at least one impedance component includes a first resistor and a first inductor that are inserted in parallel on a preceding stage side of the first overvoltage protection component, and a second resistor and a second inductor that are inserted in parallel on a preceding stage side of the second overvoltage protection component.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 13) The communication device according to Item 2, in which the at least one impedance component includes a first resistor that is inserted on a preceding stage side of the first overvoltage protection component, and a second resistor that is inserted on a preceding stage side of the second overvoltage protection component.

With this configuration, since the impedance in the

frequency band of several MHz of the protection circuit is smaller than the impedance in the frequency band of several hundred MHz, it is possible to reduce both the influence of the first peak having the frequency band of several hundred

MHz and the influence of the second peak having the frequency band of several MHz of the electrostatic noise.

(Item 14) The communication device according to Item 1, in which the high-frequency signal is transmitted by single transmission by the first signal line.

With this configuration, when single transmission is performed, the influence of the electrostatic noise applied to the communication device can be reduced.

(Item 15) The communication device according to Item 14, in which the at least one impedance component includes a resistor and an inductor that are inserted in series between the first overvoltage protection component and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 16) The communication device according to Item 14, in which the at least one impedance component includes a resistor and an inductor that are inserted in parallel between the first overvoltage protection component and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 17) The communication device according to Item 14, in which the at least one impedance component includes a resistor that is inserted between the first overvoltage protection component and the ground.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 18) The communication device according to Item 14, in which the at least one impedance component includes a resistor and an inductor that are inserted in series between the first signal line and the first overvoltage protection component.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 19) The communication device according to Item 14, in which the at least one impedance component includes a resistor and an inductor that are inserted in parallel between the first signal line and the first overvoltage protection component.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

(Item 20) The communication device according to Item 14, in which the at least one impedance component includes a resistor that is inserted between the first signal line and the first overvoltage protection component.

With this configuration, since the impedance in the frequency band of several MHz of the protection circuit is smaller than the impedance in the frequency band of several hundred MHz, it is possible to reduce both the influence of the first peak having the frequency band of several hundred MHz and the influence of the second peak having the frequency band of several MHz of the electrostatic noise.

According to the communication device of the present disclosure, it is possible to obtain a high noise reduction effect with respect to electrostatic noise.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A communication device that transmits a high-frequency signal, comprising:
at least one signal line that transmits the high-frequency signal and includes a first signal line;
at least one overvoltage protection component that is connected to the first signal line and includes a first overvoltage protection component; and
at least one impedance component that is connected in series with the first overvoltage protection component between the first signal line and a ground,
wherein the at least one impedance component achieves both reduction of current wraparound via the ground due to a high-frequency component of an electrostatic noise applied to the communication device and reduction of a current flowing through the first overvoltage protection component due to a low-frequency component of the electrostatic noise.

2. The communication device according to claim 1, wherein
the at least one signal line further includes:
a second signal line; and
at least one overvoltage protection component that is connected to the second signal line and includes a second overvoltage protection component, and
the high-frequency signal is transmitted by differential transmission by the first signal line and the second signal line.

3. The communication device according to claim 2,
wherein the at least one impedance component includes a first resistor and a first inductor that are inserted in series between the first overvoltage protection component and the ground, and a second resistor and a second inductor that are inserted in series between the second overvoltage protection component and the ground.

4. The communication device according to claim 2,
wherein the at least one impedance component includes a first resistor and a first inductor that are inserted in parallel between the first overvoltage protection component and the ground, and a second resistor and a second inductor that are inserted in parallel between the second overvoltage protection component and the ground.

5. The communication device according to claim 2,
wherein the at least one impedance component includes a first resistor that is inserted between the first overvoltage protection component and the ground, and a second resistor that is inserted between the second overvoltage protection component and the ground.

6. The communication device according to claim 2,
wherein the at least one impedance component is a ferrite bead that is inserted between a connection point between the first overvoltage protection component and the second overvoltage protection component, and the ground.

7. The communication device according to claim 2,
wherein the at least one impedance component includes a resistor and an inductor that are inserted in series between a connection point between the first overvoltage protection component and the second overvoltage protection component, and the ground.

8. The communication device according to claim 2,
wherein the at least one impedance component includes a resistor and an inductor that are inserted in parallel between a connection point between the first overvoltage protection component and the second overvoltage protection component, and the ground.

9. The communication device according to claim 2,
wherein the at least one impedance component is a resistor that is inserted between a connection point between the first overvoltage protection component and the second overvoltage protection component, and the ground.

10. The communication device according to claim 2,
wherein the at least one impedance component includes a first resistor that is inserted on a preceding stage side of the first overvoltage protection component, a first inductor that is inserted between the first overvoltage protection component and the ground, a second resistor that is inserted on a preceding stage side of the second overvoltage protection component, and a second inductor that is inserted between the second overvoltage protection component and the ground.

11. The communication device according to claim 2,
wherein the at least one impedance component includes a first resistor and a first inductor that are inserted in series on a preceding stage side of the first overvoltage protection component, and a second resistor and a second inductor that are inserted in series on a preceding stage side of the second overvoltage protection component.

12. The communication device according to claim 2,
wherein the at least one impedance component includes a first resistor and a first inductor that are inserted in parallel on a preceding stage side of the first overvoltage protection component, and a second resistor and a second inductor that are inserted in parallel on a preceding stage side of the second overvoltage protection component.

13. The communication device according to claim 2,
wherein the at least one impedance component includes a first resistor that is inserted on a preceding stage side of the first overvoltage protection component, and a second resistor that is inserted on a preceding stage side of the second overvoltage protection component.

14. The communication device according to claim 1,
wherein the high-frequency signal is transmitted by single transmission by the first signal line.

15. The communication device according to claim 14,
wherein the at least one impedance component includes a resistor and an inductor that are inserted in series between the first overvoltage protection component and the ground.

16. The communication device according to claim 14,
wherein the at least one impedance component includes a resistor and an inductor that are inserted in parallel between the first overvoltage protection component and the ground.

17. The communication device according to claim 14,
wherein the at least one impedance component includes a resistor that is inserted between the first overvoltage protection component and the ground.

18. The communication device according to claim 14,
wherein the at least one impedance component includes a resistor and an inductor that are inserted in series between the first signal line and the first overvoltage protection component.

19. The communication device according to claim 14,
wherein the at least one impedance component includes a resistor and an inductor that are inserted in parallel between the first signal line and the first overvoltage protection component.

20. The communication device according to claim 14,
wherein the at least one impedance component includes a resistor that is inserted between the first signal line and the first overvoltage protection component.
